(19) United States
(12) Patent Application Publication
(10) Pub. No.: US 2024/0297100 A1
(43) Pub. Date: Sep. 5, 2024

(54) SEMICONDUCTOR MODULE, SEMICONDUCTOR DEVICE, AND VEHICLE

(71) Applicant: FUJI ELECTRIC CO., LTD., Kawasaki-shi (JP)

(72) Inventor: Ryusuke KATO, Kawasaki-shi (JP)

(73) Assignee: FUJI ELECTRIC CO., LTD., Kawasaki-shi (JP)

(21) Appl. No.: 18/429,588

(22) Filed: Feb. 1, 2024

(30) Foreign Application Priority Data
Mar. 3, 2023 (JP) 2023-032603

(51) Int. Cl. H01L 23/495; H01L 23/00; H01L 23/31; H01L 25/065

(52) U.S. Cl. CPC H01L 23/4951; H01L 23/3142; H01L 23/49531; H01L 23/49568; H01L 24/32; H01L 24/48; H01L 25/0652; H01L 2224/32145; H01L 2224/32225; H01L 2224/48132; H01L 2224/48155; H01L 2924/01029; H01L 2924/1203; H01L 2924/13055; H01L 2924/13091; H01L 2924/183

(57) ABSTRACT

A semiconductor module includes a sealing body including a terminal portion electrically connected to a semiconductor element and an insulating resin that seals the semiconductor element, a case that houses the sealing body, and a conductive member provided in the case and including a contact portion that has contact with the terminal portion of the sealing body. The terminal portion is exposed from the insulating resin. The case includes a holding member attaching portion capable of attaching a holding member used in combination with the case and holds the sealing body in a state where the terminal portion of the sealing body has contact with the contact portion of the conductive member. The holding member attaching portion is configured so that a pressing load is applied to a contact surface of the contact portion contacting the terminal portion when the holding member is attached.

### CROSS-REFERENCE TO RELATED APPLICATION

This application is based upon and claims the benefit of priority to Japanese Patent Application No. 2023-032603, Filed on Mar. 3, 2023, the entire contents of which are incorporated herein by reference.

### BACKGROUND OF THE INVENTION

### 1. Technical Field

The present invention relates to a semiconductor module, a semiconductor device, and a vehicle.

### 2. Description of the Related Art

There is a semiconductor device used for a power conversion device such as an inverter device in which a terminal provided in a case housing a wiring board on which a semiconductor element is mounted is electrically connected to a conductor pattern of the wiring board or an electrode of the semiconductor element (for example, JP 2017-5241 A, WO 2019/135284 A, JP 2000-208686 A, and JP 10-256319 A).

### SUMMARY OF THE INVENTION

A terminal provided in a case and a conductor pattern of a wiring board in the semiconductor device described above are bonded by laser welding or ultrasonic bonding. However, with these methods, a size of the semiconductor device increases, and manufacturing cost increases.

The present invention has been made in consideration of the above, and an object of the present invention is to miniaturize a semiconductor device while suppressing an increase in manufacturing cost.

A semiconductor module according to one aspect of the present invention includes a sealing body in which a terminal portion electrically connected to an electrode of a semiconductor element is exposed from an insulating resin that seals the semiconductor element, a case including a housing portion that houses the sealing body, and a conductive member provided in the case and including a contact portion that has contact with the terminal portion of the sealing body in a case where the sealing body is housed in the housing portion of the case and an external terminal portion exposed from an outer surface of the case, in which the case includes a holding member attaching portion that is used in combination with the case and is capable of attaching a holding member that holds the sealing body housed in the housing portion in a state where the terminal portion of the sealing body has contact with the contact portion of the conductive member, and the holding member attaching portion of the case is configured so that a pressing load is applied to a contact surface between the terminal portion of the sealing body and the contact portion of the conductive member when the holding member is attached.

According to the present invention, it is possible to miniaturize a semiconductor device while suppressing an increase in manufacturing cost.

### BRIEF DESCRIPTION OF THE DRAWINGS

FIG. 1 is a top view illustrating a configuration example of a semiconductor device according to an embodiment;

FIG. 2 is a top view illustrating a configuration example of a semiconductor package included in the semiconductor device in FIG. 1;

FIG. 3 is a top view illustrating an internal configuration example of the semiconductor package in FIG. 2;

FIG. 4 is a cross-sectional side view illustrating a configuration example of the semiconductor device taken along an A-A′ line in FIG. 1;

FIG. 5 is a diagram illustrating a circuit configuration example of an inverter device to which the semiconductor device in FIG. 1 is applied;

FIG. 6 is a partially exploded perspective view for explaining fitting between a groove portion of the semiconductor package and a wall portion of a case;

FIG. 7 is a side surface cross-sectional diagram for explaining an example of a relationship between a terminal portion and the groove portion of the semiconductor package and a conductive member and the wall portion of the case;

FIG. 8 is a cross-sectional diagram for explaining a state of the terminal portion of the semiconductor package and the conductive member of the case when the cooler in which the semiconductor package is arranged is attached to the case;

FIG. 9 is a cross-sectional side view for explaining a configuration example of a mold usable for manufacturing the semiconductor package according to the present embodiment;

FIG. 10 is a cross-sectional side view for explaining an example of a transfer mold using the mold illustrated in FIG. 9;

FIG. 11 is a cross-sectional diagram for explaining another example of a method for connecting a terminal portion of a conductor pattern of the semiconductor package and the conductive member of the case;

FIG. 12 is a cross-sectional side view for explaining a modification of the conductive member provided in the case;

FIG. 13 is a cross-sectional side view illustrating a state of a connection portion between the terminal portion of the conductor pattern of the semiconductor package and the conductive member of the case in the semiconductor device using the case in FIG. 12;

FIG. 14 is a bottom view illustrating a configuration example of a case incorporating a control circuit;

FIG. 15 is a cross-sectional side view illustrating a configuration example of the case taken along a C-C′ line in FIG. 14;

FIG. 16 is a cross-sectional diagram for explaining another example of a layout of the conductive member provided in the case; and

FIG. 17 is a schematic plan view illustrating an example of a vehicle to which the semiconductor device according to the present invention is applied.

### DETAILED DESCRIPTION

Hereinafter, embodiments of the present invention will be described in detail with reference to the drawings. Note that, X, Y, and Z axes in each drawing to be referred to are illustrated for the purpose of defining a plane and a direction in the illustrated semiconductor device or the like, and the X, Y, and Z axes are orthogonal to each other and form a right-handed coordinate system. In the following description, the Z direction may be referred to as a vertical direction. Furthermore, a plane including the X axis and the Y axis may be referred to as an XY plane, a plane including the Y axis and the Z axis may be referred to as a YZ plane, and a plane including the Z axis and the X axis may be referred to as a ZX plane. Such directions and planes are terms used for convenience of description. Thus, depending of a posture of attachment of the semiconductor device, a correspondence relationship with the X, Y, and Z directions may vary. For example, here, a heat dissipation surface side (cooler side) of the semiconductor device is referred to as a lower surface side, and an opposite thereof is referred to as an upper surface side. However, the heat dissipation surface side may be referred to as the upper surface side, and the opposite side thereof may be referred to as the lower surface side. Furthermore, here, the term “in plan view” means a case where an upper surface or a lower surface (XY plane) of the semiconductor device or the like is viewed from the Z direction. Furthermore, an aspect ratio and a size relationship between the members in each drawing are merely schematically represented, and do not necessarily coincide with a relationship in a semiconductor device or the like actually manufactured. For convenience of description, it is also assumed that the size relationship between the members be exaggerated.

Furthermore, the semiconductor device to be described in the following description is applied to, for example, a power conversion device such as an inverter device of an industrial or in-vehicle motor. Thus, in the following description, detailed description of the same or similar configuration, function, operation, and the like as those of the known semiconductor device will be omitted.

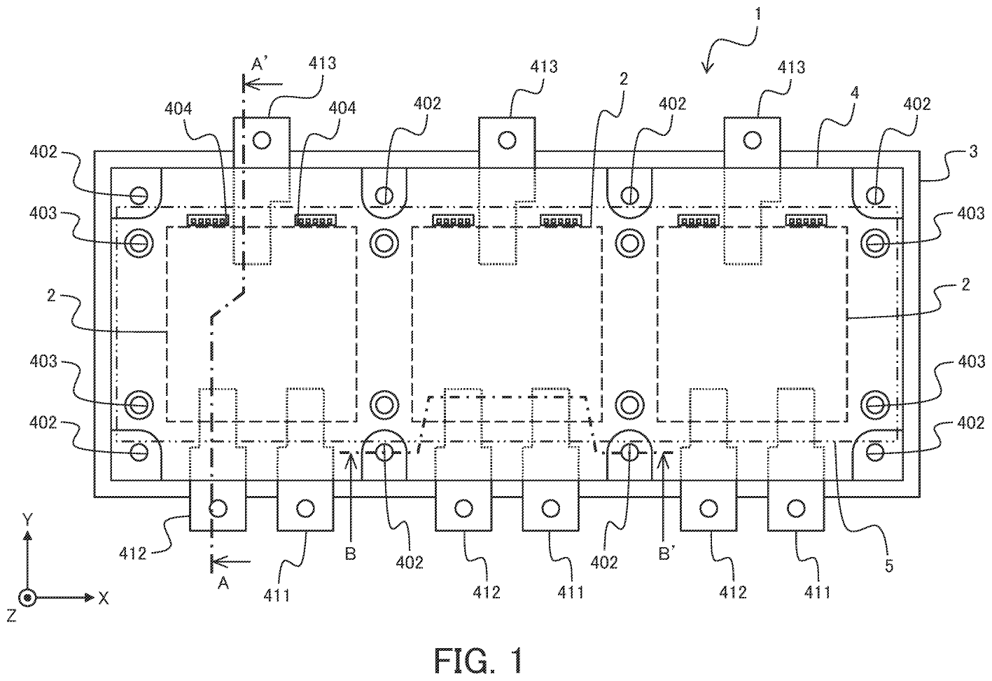

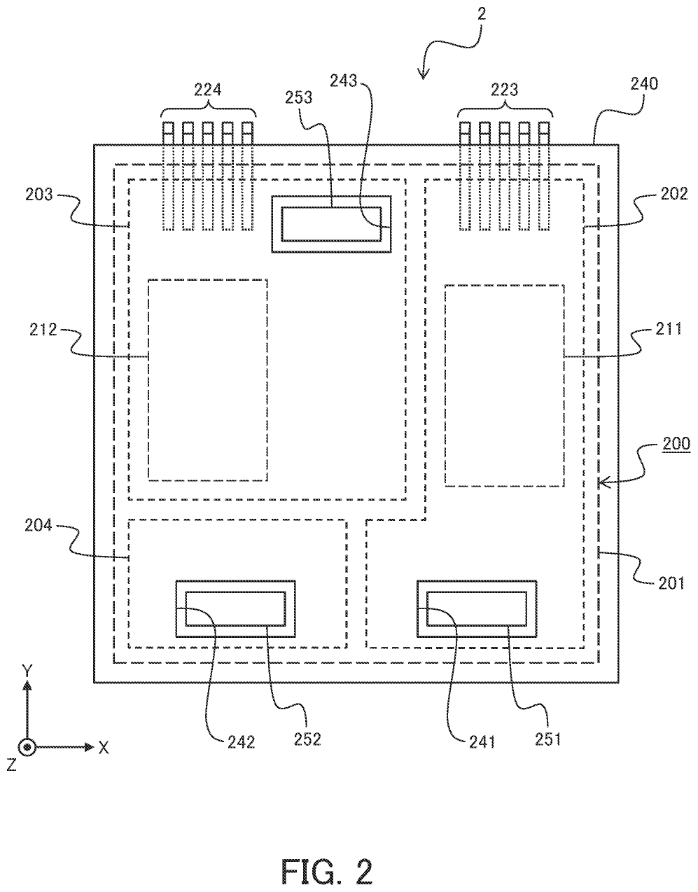

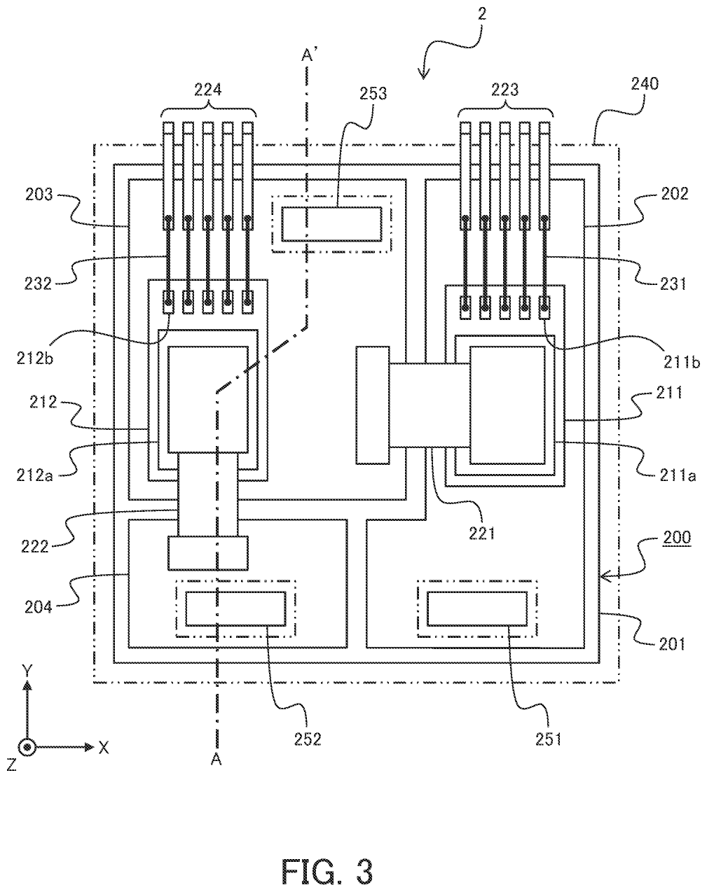

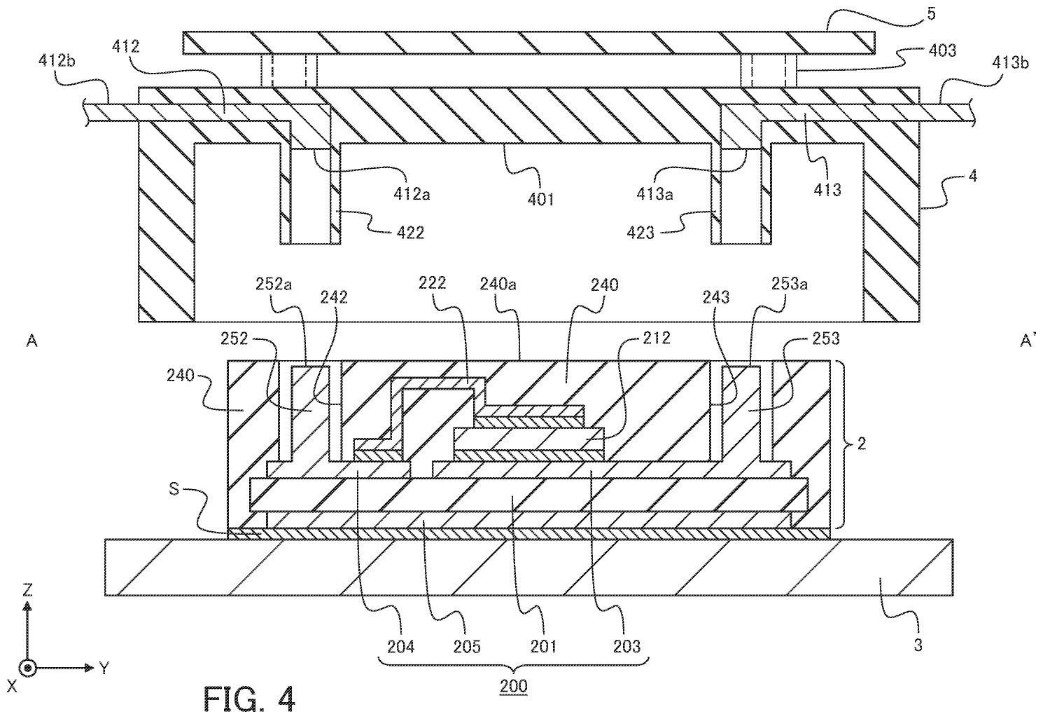

FIG. 1 is a top view illustrating a configuration example of a semiconductor device according to an embodiment. FIG. 2 is a top view illustrating a configuration example of a semiconductor package included in the semiconductor device in FIG. 1. FIG. 3 is a top view illustrating an internal configuration example of the semiconductor package in FIG. 2. FIG. 4 is a cross-sectional side view illustrating a configuration example of the semiconductor device taken along an A-A′ line in FIG. 1. In the cross-sectional side view in FIG. 4, a semiconductor package 2, a cooler 3, a case 4, and a control circuit 5, when a left portion than the A-A′ line in the semiconductor device taken along the A-A′ line in FIG. 1 is viewed from a front side in the X direction are exploded and illustrated. A portion of the A-A′ line in FIG. 1 passing through the semiconductor package 2 is illustrated in FIG. 3.

A semiconductor device 1 illustrated in FIGS. 1 to 4 includes the semiconductor package 2, the cooler 3, the case 4, and the control circuit 5.

The semiconductor device 1 illustrated in FIG. 1 includes the three semiconductor packages 2. Each semiconductor package 2 includes a wiring board 200, semiconductor elements 211 and 212, leads 221 to 224, bonding wires 231 and 232, and a mold resin 240. The semiconductor package 2 is an example of a solid state device (sealing body) in which a terminal portion electrically connected to an electrode of the semiconductor element is exposed from an insulating resin that seals the semiconductor element.

The wiring board 200 includes an insulating substrate 201, conductor patterns 202 to 204 provided on an upper surface of the insulating substrate 201, and a conductor pattern 205 provided on a lower surface of the insulating substrate 201. The wiring board 200 may be, for example, a Direct Copper Bonding (DCB) substrate or an Active Metal Brazing (AMB) substrate. The wiring board 200 may be referred to as a laminated substrate, an insulating circuit substrate, or the like.

The insulating substrate 201 is not limited to a specific substrate. The insulating substrate 201 may be, for example, a ceramic substrate made of a ceramic material such as aluminum oxide (Al₂O₃), aluminum nitride (AlN), silicon nitride (Si₃N₄), aluminum oxide (Al₂O₃), or zirconium oxide (ZrO₂). The insulating substrate 201 may be, for example, a substrate obtained by molding an insulating resin such as epoxy resin, a substrate obtained by impregnating a base material such as glass fiber with an insulating resin, a substrate obtained by coating a surface of a flat plate-shaped metal core with an insulating resin, or the like.

The conductor patterns 202 to 204 provided on the upper surface of the insulating substrate 201 are conductive components used as wiring members and are formed of, for example, a metal plate, a metal foil, or the like of copper, aluminum, or the like. The conductor patterns 202 to 204 provided on the upper surface of the insulating substrate 201 may be referred to as conductor layers, conductor plates, conductive layers, or wiring patterns. In the following description, in a case where the conductor patterns 202 to 204 are distinguished from each other, the conductor patterns 202 to 204 are respectively written as a first conductor pattern 202, a second conductor pattern 203, and a third conductor pattern 204.

The semiconductor element 211 is arranged above the first conductor pattern 202. The first conductor pattern 202 is bonded to a first main electrode (not illustrated) provided on a lower surface of the semiconductor element 211 with a bonding material (not illustrated). The bonding material is a known bonding material such as solder. Furthermore, the semiconductor element 212 is arranged above the second conductor pattern 203. The second conductor pattern 203 is bonded to the first main electrode (not illustrated) provided on a lower surface of the semiconductor element 212 with the bonding material (not illustrated).

Each of the semiconductor elements 211 and 212 includes, for example, a Reverse Conducting (RC)-IGBT element in which a function of a switching element such as an Insulated Gate Bipolar Transistor (IGBT) element and a function of a diode element such as a Free Wheeling Diode (FWD) element are integrated. Regarding each of this type of semiconductor elements 211 and 212, the first main electrode is provided on the lower surface, and a second main electrode and a control electrode (gate electrode) are provided on the upper surface.

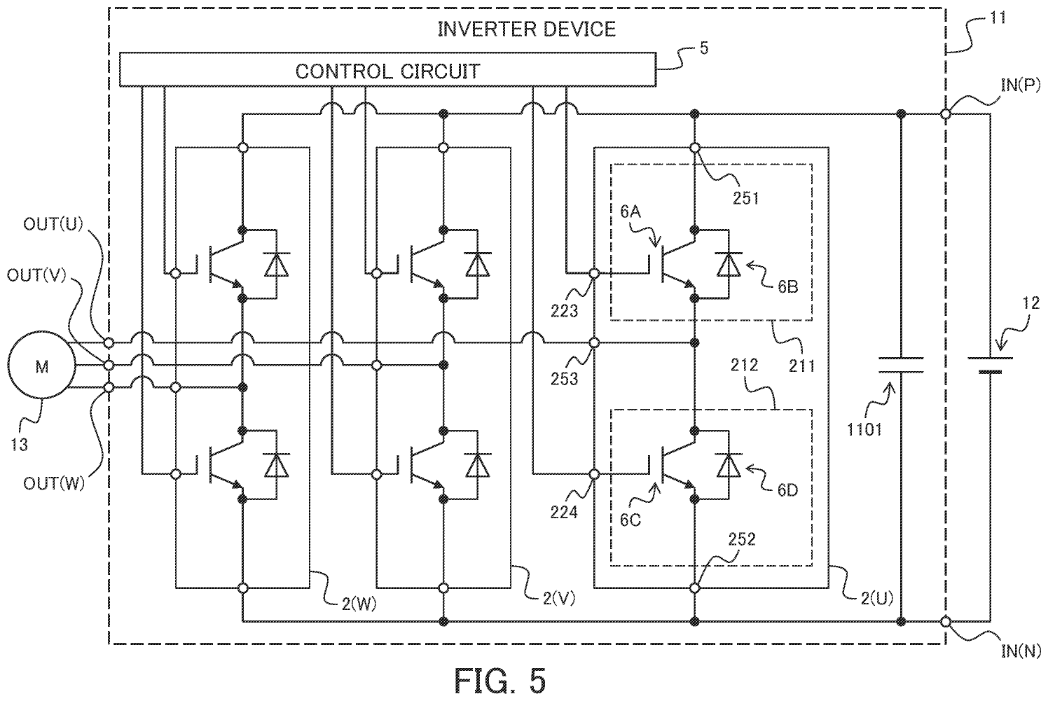

A second main electrode 211a on the upper surface of the semiconductor element 211 on the first conductor pattern 202 is electrically connected to the second conductor pattern 203 via the first lead 221. The first lead 221 is a wiring member formed by bending a conductor plate such as a copper plate and is bonded to the second main electrode 211a on the upper surface of the semiconductor element 211 and the second conductor pattern 203 with a bonding material (not illustrated). The first conductor pattern 202 includes a terminal portion 251 that is electrically connected to an input terminal (P terminal) in an inverter device 11 to be described later with reference to FIG. 5. The terminal portion 251 is exposed from an upper surface 240a of the mold resin 240 to be the upper surface of the semiconductor package 2.

A second main electrode 212a provided on the upper surface of the semiconductor element 212 arranged on the second conductor pattern 203 is electrically connected to the third conductor pattern 204 via the second lead 222. The second lead 222 is a wiring member formed by bending a conductor plate such as a copper plate. The second lead 222 is bonded to the second main electrode 212a of the semiconductor element 212 and the third conductor pattern 204, with a bonding material (not illustrated). The second conductor pattern 203 includes a terminal portion 253 that is electrically connected to an output terminal (OUT terminal) in the inverter device 11 to be described later with reference to FIG. 5. The terminal portion 253 is exposed from the upper surface 240a of the mold resin 240 to be the upper surface of the semiconductor package 2.

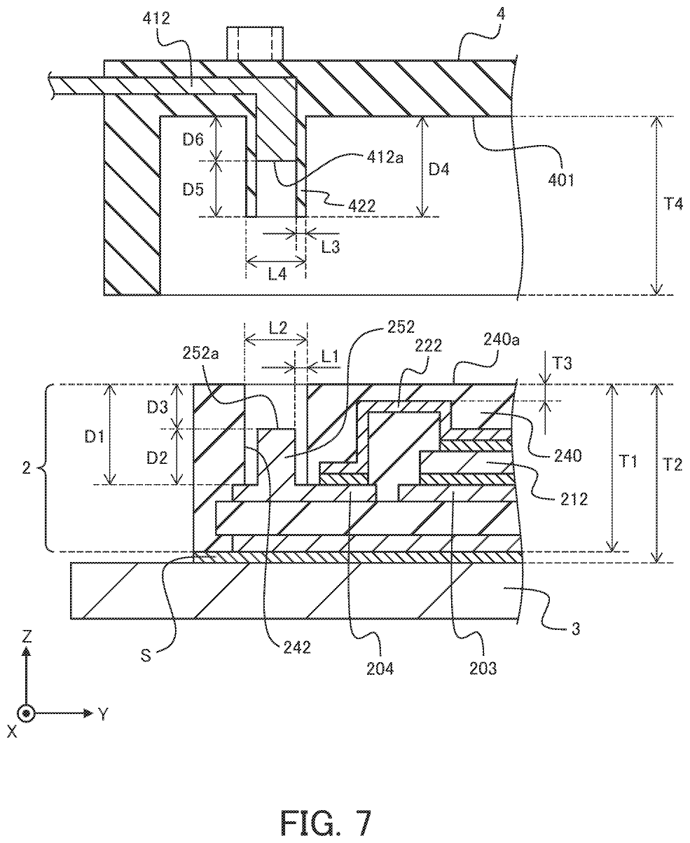

The third conductor pattern 204 includes a terminal portion 252 that is electrically connected to an input terminal (N terminal) in the inverter device 11 to be described later with reference to FIG. 5. The terminal portion 252 is exposed from the upper surface 240a of the mold resin 240 to be the upper surface of the semiconductor package 2. Note that, as described later with reference to FIG. 7, as long as the terminal portions 251 to 253 are exposed from the upper surface 240a of the mold resin 240 to be the upper surface of the semiconductor package 2 and an upper surface of each of the terminal portions 251 to 253 in the semiconductor package 2 housed in the case 4 can have contact with contact portions of conductive members 411 to 413 of the case 4, a height (dimension in Z direction) of the terminal portions 251 to 253 is not particularly limited. For example, positions in the Z direction on an upper surface 252a of the terminal portion 252 and an upper surface 253a of the terminal portion 253 illustrated in FIG. 4 may be the same position as that on the upper surface 240a of the mold resin 240.

A control electrode 211b provided on the upper surface of the semiconductor element 211 is electrically connected to the third lead 223 by the bonding wire 231. A control electrode 212b provided on the upper surface of the semiconductor element 212 is electrically connected to the fourth lead 224 by the bonding wire 232. The third lead 223 and the fourth lead 224 are wiring members formed by using a conductor plate such as a copper plate. The third lead 223 and the fourth lead 224 have a portion protruding from a side surface of the mold resin 240, and the portion protruding from the mold resin 240 is bent and extends upward (+Z direction). Front end portions of the third lead 223 and the fourth lead 224 that protrude from the mold resin 240 and extends upward pass through a through-hole 404 provided in the case 4 and are connected to the control circuit 5 arranged on the case 4. Note that the number of the third leads 223 and the fourth leads 224 is not limited to five illustrated in FIGS. 2 and 3. Furthermore, the side surface of the mold resin 240 from which the third lead 223 and the fourth lead 224 protrude is not limited to a side surface (end surface in +Y direction) of the mold resin 240 close to the terminal portion 253 of the second conductor pattern 203, as illustrated in FIGS. 2 and 3.

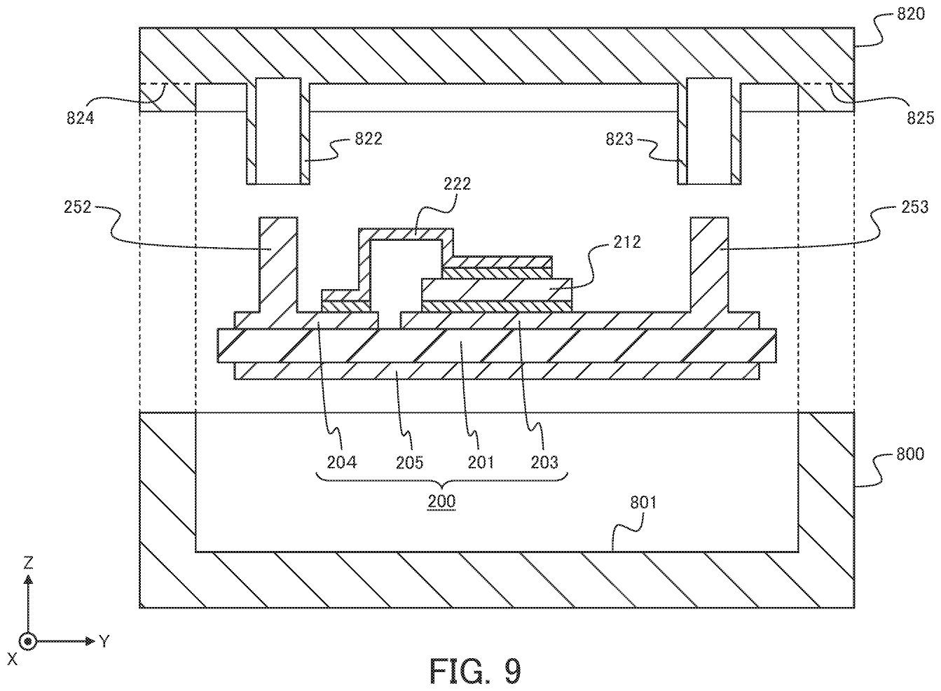

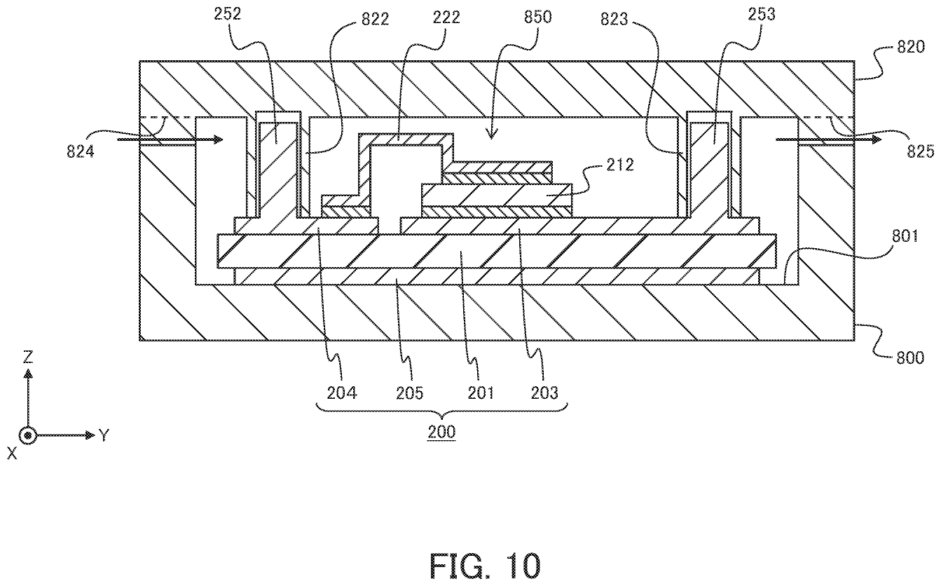

The conductor patterns 202 to 204 of the wiring board 200, the semiconductor elements 211 and 212, all of the first lead 221 and the second lead 222, and a part of the third lead 223, and a part of the fourth lead 224 are sealed with the mold resin 240. The semiconductor package 2 according to the present embodiment is manufactured by transfer mold to be described later with reference to FIGS. 9 and 10, for example.

The semiconductor device 1 illustrated in FIG. 1 includes the three semiconductor packages 2 and can form, for example, a three-phase inverter circuit.

FIG. 5 is a diagram illustrating a circuit configuration example of an inverter device to which the semiconductor device in FIG. 1 is applied.

In FIG. 5, as an example of the inverter device 11, an example of a circuit configuration of a voltage-type three-phase inverter device is illustrated. The inverter device 11 includes the three semiconductor packages 2 (U), 2 (V), and 2 (W) that operate as conversion circuits, a smoothing capacitor 1101, and the control circuit 5. The semiconductor package 2 (U) converts a direct current into an alternating current and outputs the alternating current as a U-phase alternating current. The semiconductor package 2 (V) converts a direct current into an alternating current and outputs the alternating current as a V-phase alternating current. The semiconductor package 2 (W) converts a direct current into an alternating current and outputs the alternating current as a W-phase alternating current. Here, three phases in the three-phase alternating current are referred to as the U phase, the V phase, and the W phase. However, the three phases may be referred to as other terms.

In the inverter device 11, the three semiconductor packages 2 (U), 2 (V), and 2 (W), and the smoothing capacitor 1101 are connected in parallel. A circuit configuration of each of the three semiconductor packages 2 (U), 2 (V), and 2 (W) illustrated as an equivalent circuit in FIG. 5 corresponds to the circuit configuration of the single semiconductor package 2 described above with reference to FIGS. 3 and 4 or the like. In the inverter device 11 illustrated in FIG. 5, the three semiconductor packages 2 (U), 2 (V), and 2 (W) are arranged along the X direction in FIG. 1, for example.

The inverter device 11 has a first input terminal IN (P) that connects a positive terminal of a direct current power supply 12, a second input terminal IN (N) that connects a negative terminal of the direct current power supply 12, and output terminals OUT (U), OUT (V), and OUT (W) that output three-phase alternating currents.

In each of the semiconductor packages 2 (U), 2 (V), and 2 (W), a collector electrode of the semiconductor element 211 connected between the first input terminal IN (P) that may be referred to as an upper arm and the output terminals OUT (U), OUT (V), and OUT (W) is connected to the first input terminal IN (P) via a terminal (terminal portion 251 of first conductor pattern 202). Furthermore, in each of the semiconductor packages 2 (U), 2 (V), and 2 (W), an emitter electrode of the semiconductor element 212 connected between the second input terminal IN (N) that may be referred to as a lower arm and the output terminals OUT (U), OUT (V), and OUT (W) is connected to the second input terminal IN (N) via a terminal (terminal portion 252 of third conductor pattern 204).

The emitter electrode of the semiconductor element 211 of the upper arm and the collector electrode of the semiconductor element 212 of the lower arm in the semiconductor package 2 (U) are connected to the output terminal OUT (U) that outputs a U-phase alternating current in the three-phase alternating current, via a terminal (terminal portion 253 of second conductor pattern 203). The emitter electrode of the semiconductor element 211 of the upper arm and the collector electrode of the semiconductor element 212 of the lower arm in the semiconductor package 2 (V) are connected to the output terminal OUT (V) that outputs a V-phase alternating current in the three-phase alternating current, via a terminal (terminal portion 253 of second conductor pattern 203). The emitter electrode of the semiconductor element 211 of the upper arm and the collector electrode of the semiconductor element 212 of the lower arm in the semiconductor package 2 (W) are connected to the output terminal OUT (W) that outputs a W-phase alternating current in the three-phase alternating current, via a terminal (terminal portion 253 of second conductor pattern 203). The alternating current output from each of the semiconductor packages 2 (U), 2 (V), and 2 (W) is controlled to have phases different by 120 degrees, by a control signal applied from the control circuit 5 to a gate (control electrode 211b) of a switching element 6A of the upper-arm semiconductor element 211 via the third lead 223 and a control signal applied to a gate of a switching element 6C of the lower-arm semiconductor element 212 via the fourth lead 224. The output terminals OUT (U), OUT (V), and OUT (W) of the inverter device 11 are connected to a load (for example, AC motor) 13 that operates with an alternating current.

Note that the circuit configuration of the inverter device 11 including the semiconductor package 2 according to the present embodiment is not limited to the circuit configuration illustrated in FIG. 5. Furthermore, an operation of the inverter device 11 including the semiconductor package 2 according to the present embodiment is not limited to a specific operation.

Moreover, the inverter device 11 described above with reference to FIG. 5 is merely an example of a device to which the semiconductor device 1 according to the present embodiment is applied.

In a case where the switching elements 6A and 6C of the semiconductor elements 211 and 212 are IGBT elements, as described above, main electrodes on a lower surface side of the semiconductor elements 211 and 212 are referred to as collector electrodes, and the main electrodes 211a and 212a on the upper surface side are referred to as an emitter electrode. In a case where the switching elements 6A and 6C are MOSFET elements, the main electrodes on the lower surface side of the semiconductor elements 211 and 212 may be referred to as a drain electrode, and the main electrodes 211a and 212a on the upper surface side may be referred to as a source electrode. Furthermore, the control electrodes 211b and 212b provided on the upper surfaces of the semiconductor elements 211 and 212 may include a gate electrode and an auxiliary electrode. For example, the auxiliary electrode may be an auxiliary emitter electrode or an auxiliary source electrode electrically connected to the main electrode on the upper surface side and serving as a reference potential with respect to a gate potential. Furthermore, the auxiliary electrode may be a temperature sense electrode that is electrically connected to a temperature sense unit that may be included in the inverter device 11 including the semiconductor package 2 or the like and measures temperatures of the semiconductor elements 211 and 212. These electrodes (main electrode and control electrode including gate electrode and auxiliary electrode) formed on the upper surfaces of the semiconductor elements 211 and 212 may be collectively referred to as upper surface electrodes.

Furthermore, the switching element 6A and a diode element 6B illustrated to be included in the single semiconductor element 211 in FIG. 5 may be different semiconductor elements. Similarly, the switching element 6C and a diode element 6D illustrated to be included in the single semiconductor element 212 in FIG. 5 may be different semiconductor elements.

As illustrated in FIG. 4, the three semiconductor packages 2 in the semiconductor device 1 according to the present embodiment are arranged on an upper surface of the cooler 3. In the semiconductor package 2, the fourth conductor pattern 205 provided on the lower surface of the insulating substrate 201 in the wiring board 200 is exposed from the mold resin 240, and for example, a lower surface of the fourth conductor pattern 205 and the upper surface of the cooler 3 are bonded with a bonding material S. The cooler 3 may be referred to as a heat dissipation plate or a heat dissipation layer. The semiconductor package 2 may be arranged on the upper surface of the cooler 3, for example, via a thermal conductive material such as thermal grease or thermal compound.

The cooler 3 releases heat of the semiconductor package 2 to the outside, and has a rectangular parallelepiped shape as a whole. Although not particularly illustrated, the cooler 3 is configured by providing a plurality of fins on a lower surface side of a flat plate-shaped base portion and housing these fins in a water jacket. Note that the shape and the configuration of the cooler 3 are not limited to those, and can be appropriately changed. Furthermore, the semiconductor package 2 may be arranged on an upper surface of another member (for example, base plate) different from the cooler 3, and a lower surface of the another member may be connected to the cooler 3.

The case 4 is a member that covers the semiconductor package 2 arranged on the cooler 3, and includes a housing portion 401 that house the semiconductor package 2, a first attaching portion (holding member attaching portion) 402 to which the cooler 3 is attached, and a second attaching unit (circuit component attaching portion) 403 to which the control circuit 5 is attached. Furthermore, the case 4 has the through-hole 404 used to connect the third lead 223 and the fourth lead 224 that protrude from the semiconductor package 2 housed in the housing portion 401 and extend upward to the control circuit 5.

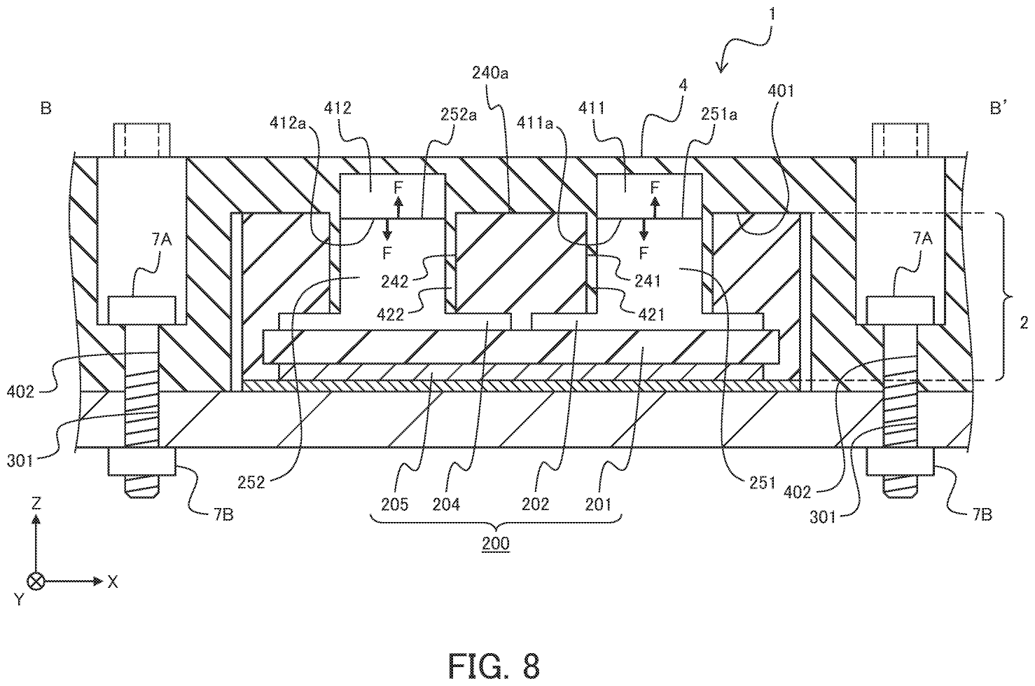

The housing portion 401 defines a recessed space with an open lower surface side. The first attaching portion 402 is configured to be able to attach the cooler 3 to the case 4 in a state where the upper surface of the cooler 3 and the lower surface of the case 4 face each other. The first attaching portion 402 is, for example, a through-hole that passes through from the lower surface to the upper surface to be described later with reference to FIG. 8, and the cooler 3 is attached to the case 4 by performing alignment with the through-hole (through-hole 301 in FIG. 8) of the cooler 3 and fastening the through-holes with a bolt or the like. The second attaching unit 403 is configured to be able to attach the control circuit 5 arranged above the case 4 to the case 4. The second attaching unit 403 has, for example, a screw hole, and the control circuit 5 is attached to the case 4 by performing alignment with the through-hole of the control circuit 5 and fixing the holes with a screw or the like.

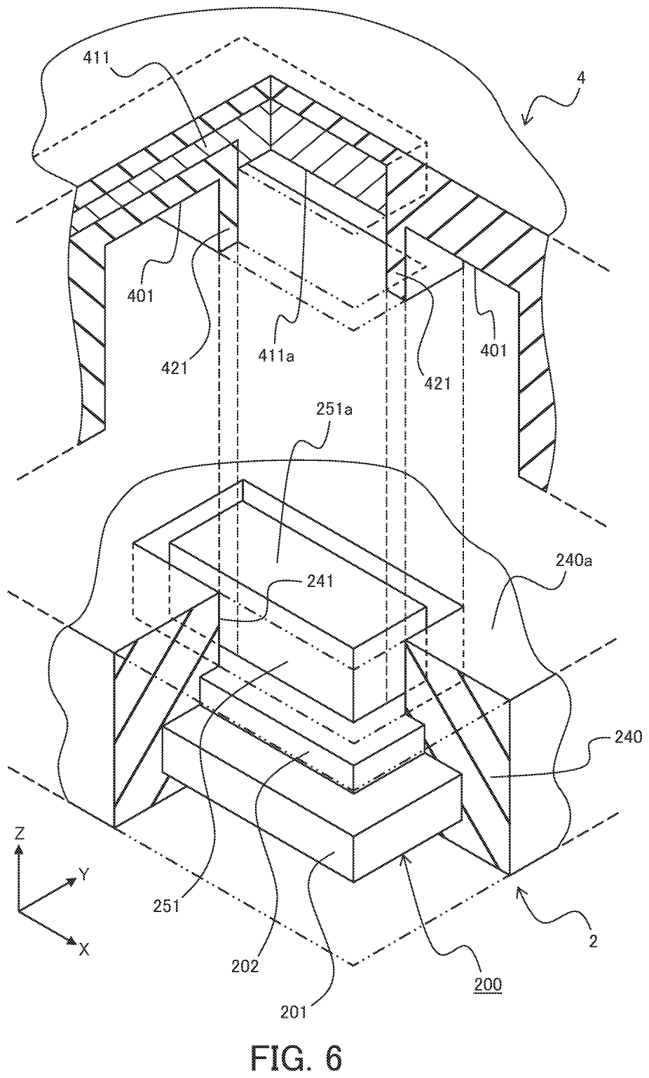

Furthermore, the case 4 includes the conductive members 411 to 413 that are electrically connected to the respective terminal portions 251 to 253 of the semiconductor package 2. The conductive member 411 corresponds to the first input terminal IN (P) in the inverter device 11 described above with reference to FIG. 5. The conductive member 411 includes a contact portion 411a (refer to FIG. 6) that has contact with an upper surface 251a of the terminal portion 251 provided on the first conductor pattern 202 of the semiconductor package 2 facing the housing portion 401 and an external terminal portion that is exposed to an outer surface of the case 4. The conductive member 412 corresponds to the second input terminal IN (N) in the inverter device 11 described above with reference to FIG. 5. The conductive member 412 includes a contact portion 412a that has contact with the upper surface 252a of the terminal portion 252 of the third conductor pattern 204 of the semiconductor package 2 facing the housing portion 401 and an external terminal portion 412b exposed to the outer surface of the case 4. The conductive member 413 corresponds to the output terminal OUT in the inverter device 11 described above with reference to FIG. 5. The conductive member 413 includes a contact portion 413a that has contact with the upper surface 253a of the terminal portion 253 of the second conductor pattern 203 of the semiconductor package 2 facing the housing portion 401 and an external terminal portion 413b exposed to the outer surface of the case 4. In the external terminal portion of each of the conductive members 411 to 413, for example, a through-hole is provided as illustrated in FIG. 1. The through-hole of the external terminal portion is, for example, used as a screw hole that is used when a terminal of a conductive cable such as a wire harness is connected to the external terminal portion.

Moreover, in the mold resin 240 of the semiconductor package 2, different groove portions 241 to 243 extending downward from the upper surface 240a so as to respectively surround the terminal portions 251 to 253 in plan view are provided. On the other hand, in the housing portion 401 of the case 4, different wall portions 421 to 423 that can enter the respective groove portions 241 to 243 of the semiconductor package 2 are provided.

FIG. 6 is a partially exploded perspective view for explaining fitting between a groove portion of the semiconductor package and a wall portion of the case. FIG. 7 is a side surface cross-sectional diagram for explaining an example of a relationship between the terminal portion and the groove portion of the semiconductor package and the conductive member and the wall portion of the case. FIG. 8 is a cross-sectional diagram for explaining a state of the terminal portion of the semiconductor package and the conductive member of the case when the cooler in which the semiconductor package is arranged is attached to the case. Note that FIG. 7 illustrates a left half of the semiconductor device 1 illustrated in FIG. 4. Furthermore, FIG. 8 is a view of a portion upper than a B-B′ line in the semiconductor device taken along the B-B′ line in FIG. 1 as viewed from below. Furthermore, in FIG. 8, hatching indicating cross sections of the first conductor pattern 202 and the second conductor pattern 203 of the semiconductor package 2 and hatching indicating cross sections of the conductive members 411 and 412 of the case 4 are omitted.

In FIG. 6, a configuration example of fitting between the groove portion 241 surrounding the terminal portion 251 of the first conductor pattern 202 in the semiconductor package 2 and the wall portion 421 of the case 4 is illustrated. The groove portion 241 of the semiconductor package 2 has a square annular opening end surrounding the terminal portion 251 in plan view on the upper surface of the semiconductor package 2 (upper surface 240a of mold resin 240) and extends downward from the upper surface of the semiconductor package 2. On a bottom surface of the groove portion 241, a portion positioned on an outer side of the terminal portion 251 in plan view in the first conductor pattern 202 is exposed. On the other hand, the wall portion 421 of the case 4 defines a recess portion having a shape substantially the same as or a shape including the shape of the terminal portion 251 of the first conductor pattern 202 in plan view, and extends downward from a bottom surface of the housing portion 401 so that the contact portion 411a of the conductive member 411 is exposed to a bottom surface of the recess portion. A height (dimension in Z direction) of the wall portion 421 is designed to be a dimension such that the upper surface 251a of the terminal portion 251 provided on the first conductor pattern 202 has contact with the contact portion 411a of the conductive member 411 when the cooler 3, to which the semiconductor package 2 is arranged, is attached to the case 4. A height of the wall portion 422 is designed to be a dimension such that the upper surface 252a of the terminal portion 252 provided on the third conductor pattern 204 has contact with the contact portion 412a of the conductive member 412. A height of the wall portion 423 is designed to be a dimension such that the upper surface 253a of the terminal portion 253 provided on the second conductor pattern 203 has contact with the contact portion 413a of the conductive member 413.

For example, as illustrated in FIG. 7, in the semiconductor package 2, a thickness T3 of the mold resin 240 on the second lead 222 and the first lead 221 (not illustrated) is designed to sufficiently secure insulating property, and whereby an entire thickness T1 is determined. In a case where the semiconductor package 2 is bonded to the upper surface of the cooler 3 with the bonding material S, a thickness T2 from the upper surface of the cooler 3 to the upper surface of the semiconductor package 2 (upper surface 240a of mold resin 240) is a value obtained by adding a thickness (not illustrated) of the bonding material S to the thickness T1 of the semiconductor package 2. Therefore, a depth T4 of the housing portion 401 provided in the case 4 to which the cooler 3 in which the semiconductor package 2 is arranged is attached substantially coincides with the thickness T2 from the upper surface of the cooler 3 to the upper surface of the semiconductor package 2 (upper surface 240a of mold resin 240). In such a semiconductor device 1 in which the semiconductor package 2 and the case 4 are combined, the thickness T1 of the semiconductor package 2 can be set to a thickness that does not depend on the heights of the terminal portions 251 to 253.

In a case where the groove portion (for example, groove portion 242) of the semiconductor package 2 is formed so that the third conductor pattern 204 is exposed from the bottom surface as illustrated in FIG. 7, a height D4 of the wall portion 422 from the bottom surface of the housing portion 401 of the case 4 is made smaller than a depth D1 of the groove portion 242. Furthermore, by adjusting dimensions L1 and L2 indicating a width of the groove portion 242 of the semiconductor package 2 and dimensions L3 and L4 indicating a width of the wall portion 422 of the case 4, it is possible to make the wall portion 422 enter the groove portion 242. As a result, in a state where the wall portion 422 of the case 4 enters the groove portion 242 of the semiconductor package 2, a state is made where the upper surface of the cooler 3 and the lower surface of the case 4 have contact with each other or are very close to each other, and the cooler 3 can be attached to the case 4.

Moreover, the height D2 of the terminal portion 252 and a protrusion amount D6 of the conductive member 412 from the bottom surface of the housing portion 401 are set to be D1≈D2+D6 (≈D4). That is, a height D3 from the upper surface 252a of the terminal portion 252 to the upper surface 240a of the mold resin 240 and the protrusion amount D6 from the bottom surface of the housing portion 401 in the conductive member 412 are set to be D3≈D6, and a height D5 of the wall portion 422 from the contact portion 412a of the conductive member 412 and the height D2 of the terminal portion 252 are set to be D2≈D5. As a result, when the cooler 3 in which the semiconductor package 2 is arranged is attached to the case 4, it is possible to make the upper surface 252a of the terminal portion 252 of the third conductor pattern 204 have contact with the contact portion 412a of the conductive member 412 of the case 4.

Furthermore, although detailed description is omitted, a portion where the terminal portion 251 of the first conductor pattern 202 of the semiconductor package 2 has contact with the conductive member 411 of the case 4 and a portion where the terminal portion 253 of the second conductor pattern 203 of the semiconductor package 2 has contact with the conductive member 413 of the case 4 are set to have a similar configuration and similar dimensions. As a result, when the cooler 3 in which the semiconductor package 2 is arranged is attached to the case 4, it is possible to make the upper surfaces of the respective terminal portions 251 and 253 have contact with the contact portions 411a and 413a of the conductive members 411 and 413.

In this way, in the semiconductor device 1 according to the present embodiment, when the cooler 3 in which the semiconductor package 2 is arranged is attached to the case 4, the three terminal portions 251 to 253 exposed to the upper surface of the semiconductor package 2 respectively have contact with the contact portions 411a to 413a of the conductive members 411 to 413 of the case 4. Moreover, as illustrated in FIG. 8, by fastening a bolt 7A and a nut 7B used to attach the cooler 3 to the case 4, a pressing load F is applied to contact surfaces between the terminal portions 251 to 253 of the semiconductor package 2 and the contact portions 411a to 413a of the conductive members of the case 4, and the terminal portions 251 to 253 and the contact portions 411a to 413a are mechanically firmly connected. That is, in the semiconductor device 1 according to the present embodiment, it is possible to secure electrical connection between the conductive member of the case 4 and the conductor pattern of the wiring board 200 of the semiconductor package 2, without performing laser welding, ultrasonic bonding, or the like. Furthermore, since the semiconductor device 1 according to the present embodiment is in a state where the terminal portions 251 to 253 of the semiconductor package 2 have mechanical contact with the contact portions 411a to 413a of the conductive members of the case 4 by the pressing load, the semiconductor package 2 can be easily removed from the case 4, and a work such as exchange of the semiconductor package 2 can be easily performed. Furthermore, since the wall portions 421 to 423 provided on the housing portion 401 of the case 4 enter the respective groove portions 241 to 243 of the semiconductor package 2, it is possible to perform alignment so as to make the terminal portions 251 to 253 of the semiconductor package 2 have contact with the contact portions 411a to 413a of the conductive members of the case 4.

In a case where the pressing load F is applied to the contact surfaces between the terminal portions 251 to 253 of the semiconductor package 2 and the contact portions 411a to 413a of the conductive members of the case 4 by fastening the bolt 7A and the nut 7B, it is preferable to set a fastening position to be close to the terminal portions 251 to 253 exposed from the upper surface of the semiconductor package 2. Furthermore, as illustrated in FIG. 8, in a case where the upper surface of the semiconductor package 2 (upper surface 240a of mold resin 240) has contact with the bottom surface of the housing portion 401 of the case 4, a pressing load is applied to this contact surface. Therefore, for example, in order to avoid application of excessive stress to portions where the semiconductor elements 211 and 212 are arranged on the wiring board 200 by fastening the bolt 7A and the nut 7B, it is preferable to make the fastening position to be separated from the semiconductor elements 211 and 212. Therefore, in a case where the cooler 3 is attached to the case 4 using the bolt 7A and the nut 7B, as illustrated in FIG. 1, it is preferable that a position of the first attaching portion 402 in the case 4 that is a through-hole of the bolt 7A be a position to be an outer peripheral portion of the case 4 in plan view on a surface of the case 4 to which the cooler 3 is attached. It is more preferable that the attachment position of the first attaching portion 402 be a position corresponding to a corner portion of the semiconductor package 2 housed in the case 4 in plan view.

Note that a method for attaching the cooler 3 to the case 4 is not limited to the method for fastening the cooler 3 to the case 4 using the bolt 7A and the nut 7B. For example, the case 4 and the cooler 3 may be sandwiched by a clip.

FIG. 9 is a cross-sectional side view for explaining a configuration example of a mold usable for manufacturing the semiconductor package according to the present embodiment. FIG. 10 is a cross-sectional side view for explaining an example of a transfer mold using the mold illustrated in FIG. 9.

The semiconductor package 2 that can be used for the semiconductor device 1 according to the present embodiment can be manufactured by a known method. A manufacturing process of the semiconductor package 2 is roughly divided into, for example, a process for manufacturing the wiring board 200, a process for forming a circuit by arranging the semiconductor element and the lead on the upper surface of the wiring board 200, and a process for sealing a circuit on the wiring board 200.

The process for sealing the circuit on the wiring board 200 is performed, for example, by the transfer mold. For example, as illustrated in FIGS. 9 and 10, a circuit board in which a circuit including the semiconductor elements 211 and 212, the leads 221 and 222, and the like are formed on the upper surface of the wiring board 200 is arranged in a space (cavity) 850 defined by a lower mold 800 and an upper mold 820 of a mold. In the lower mold 800, for example, a recessed circuit board housing portion having a bottom surface 801 that has close contact with the lower surface of the fourth conductor pattern 205 in the wiring board 200 is provided. In the upper mold 820, wall portions 821 to 823 used to respectively form the groove portions 241 to 243 in the mold resin 240 of the semiconductor package 2 are provided. Similarly to the wall portions 421 to 423 of the case 4 described above with reference to FIG. 6 or the like, the wall portions 821 to 823 define recess portions having a shape substantially the same as or a shape including the shape of the terminal portions 251 to 253 in plan view. Note that it is preferable that the wall portions 821 to 823 be provided so that a front end surface (lower end surface) has contact with an upper surface of a portion positioned outside of the terminal portion in plan view, of the conductor patterns 202 to 204 including the terminal portion when the lower mold 800 and the upper mold 820 are fastened. Furthermore, for example, in the upper mold 820, an opening portion 824 to be an injection port (gate) through which the mold resin 240 is injected into the cavity 850 when the lower mold 800 and the upper mold 820 are fastened and an opening portion 825 to be an exhaust port. By using such a lower mold 800 and upper mold 820, when the mold resin 240 is injected into the cavity 850, the groove portions 241 to 243 in which the upper surface 240a of the mold resin 240 opens are formed around the respective terminal portions 251 to 253. Note that the method for sealing the semiconductor elements 211 and 212 or the like on the wiring board 200 with the insulating material is not limited to the transfer mold described above.

When a typical semiconductor device similar to the semiconductor device 1 according to the present embodiment is manufactured, for example, after the process for electrically connecting the conductor pattern of the wiring board 200 on which the semiconductor element or the like is arranged and the circuit is formed and the conductive members 411 to 413 provided in the case of which the upper surface opens, a process for sealing the semiconductor element or the like in the case with an insulating resin is performed. In such a manufacturing process, the conductor pattern of the wiring board 200 and the conductive members 411 to 413 of the case are bonded, by laser welding or ultrasonic bonding.

However, in the laser welding, for example, the insulating substrate 201 of the wiring board 200 may be damaged or a bonding material (for example, solder) may be flow out due to heat. Therefore, the terminal portions 251 to 253 need to have a certain height (dimension in Z direction). Moreover, in the ultrasonic bonding, an area that can be bonded in one processing is limited. When a bonding area between the conductor pattern of the wiring board 200 and the conductive member of the case increases, the number of times of bonding processing increases, and manufacturing cost increases.

On the other hand, as described above, the semiconductor device 1 according to the present embodiment houses the semiconductor package 2, in which the semiconductor element or the like is arranged on the wiring board 200 and the circuit is formed, sealed with the insulating resin in the housing portion 401 of the case 4, and secures electrical connection between the terminal portions 251 to 253 exposed from the mold resin 240 of the semiconductor package 2 and the conductive members 411 to 413 of the case 4 by the pressing load F applied to the contact surface therebetween. Furthermore, as described above with reference to FIG. 7, in the semiconductor device 1 according to the present embodiment, the thickness T1 of the semiconductor package 2 can be set to a thickness that does not depend on the heights of the terminal portions 251 to 253, in other words, the positions of the upper surfaces 251a to 253a of the respective terminal portions 251 to 253 in the vertical direction can be set to be lower than the upper surface of the mold resin 240. Therefore, it is possible to prevent the insulating substrate 201 from being damaged and to suppress the height of the terminal portions 251 to 253 (dimension in Z direction). Furthermore, the number of processes for bonding the terminal portions 251 to 253 to the conductive members 411 to 413 of the case 4 can be reduced. Accordingly, the semiconductor device 1 can be miniaturized while suppressing the increase in the manufacturing cost. Note that the electrical connection between the terminal portions 251 to 253 of the semiconductor package 2 and the conductive members 411 to 413 of the case 4 in the semiconductor device 1 according to the present embodiment may involve partial bonding caused by the ultrasonic bonding or the like, for example.

The method for securing the electrical connection between the terminal portions 251 to 253 of the conductor pattern of the semiconductor package 2 and the conductive members 411 to 413 of the case 4 in the semiconductor device 1 according to the present embodiment by the pressing load is not limited to the above method.

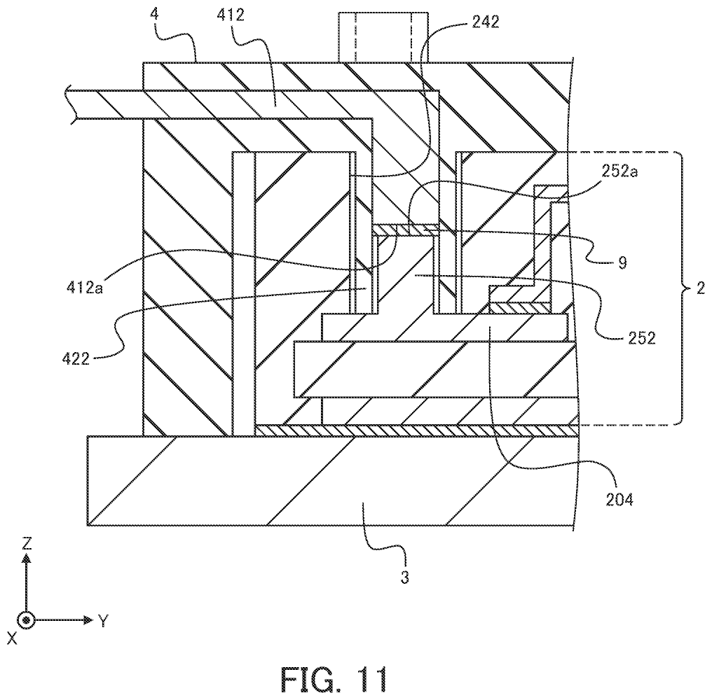

FIG. 11 is a cross-sectional diagram for explaining another example of a method for connecting the terminal portion of the conductor pattern of the semiconductor package and the conductive member of the case.

In FIG. 11, an enlarged connection portion between the terminal portion 252 of the third conductor pattern 204 of the semiconductor package 2 and the contact portion 412a of the conductive member 412 of the case 4 is illustrated. In the example in FIG. 11, the terminal portion 252 and the conductive member 412 are electrically connected via an adhesive conductor layer 9. That is, in the example in FIG. 11, the terminal portion 252 and the semiconductor package 2 and the conductive member 412 of the case 4 apply the pressing load to each other via the adhesive conductor layer 9. For example, to the upper surface 252a of the terminal portion 252 of the semiconductor package 2, the pressing load from the conductive member 412 of the case 4 is applied via the adhesive conductor layer 9. The adhesive conductor layer 9 may be, for example, a member that can fill a gap (air gap) between the upper surface 252a of the terminal portion 252 of the conductor pattern and the lower surface (contact portion 412a) of the conductive member 412, such as a conductive paste or a conductive tape. In the example in FIG. 11, for example, since the cooler 3 is attached to the case 4 in a state where the adhesive conductor layer 9 is arranged on the upper surface 252a of the terminal portion 252 or the contact portion 412a of the conductive member 412, the adhesive conductor layer 9 may be regarded as a part of the terminal portion 252 or a part of the conductive member 412. By using such an adhesive conductor layer 9, adhesiveness between the terminal portion 252 and the conductive member 412 is improved, and it is possible to reduce heat generation of the conductive member 412 due to contact resistance.

In a case where the conductive paste is used as the adhesive conductor layer 9, as illustrated in FIG. 11, it is preferable that the wall portion 422 of the case 4 be fitted into the groove portion 242 of the semiconductor package 2 and the front end surface (lower end surface) of the wall portion 422 have contact with the upper surface of the third conductor pattern 204. In this way, for example, it is possible to prevent deterioration in electrical characteristics or the like due to the adhesive conductor layer 9 protruding from between the upper surface 252a of the terminal portion 252 of the conductor pattern and the lower surface (contact portion 412a) of the conductive member 412.

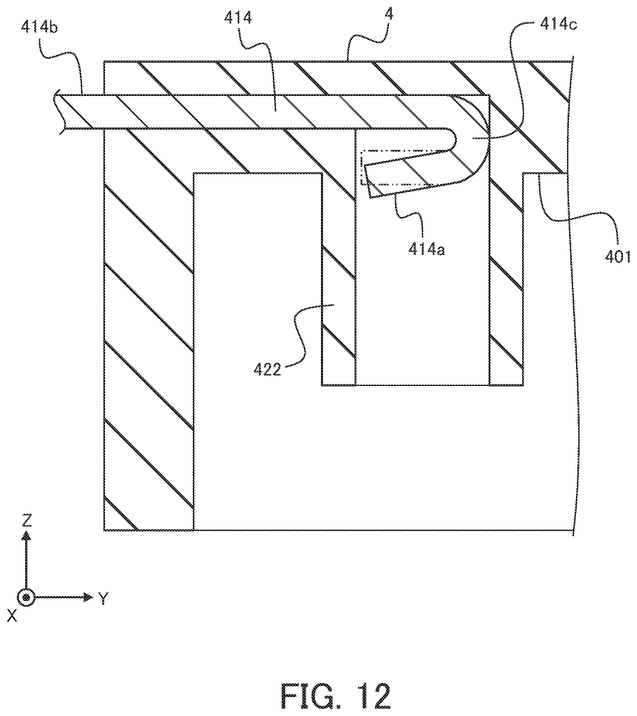

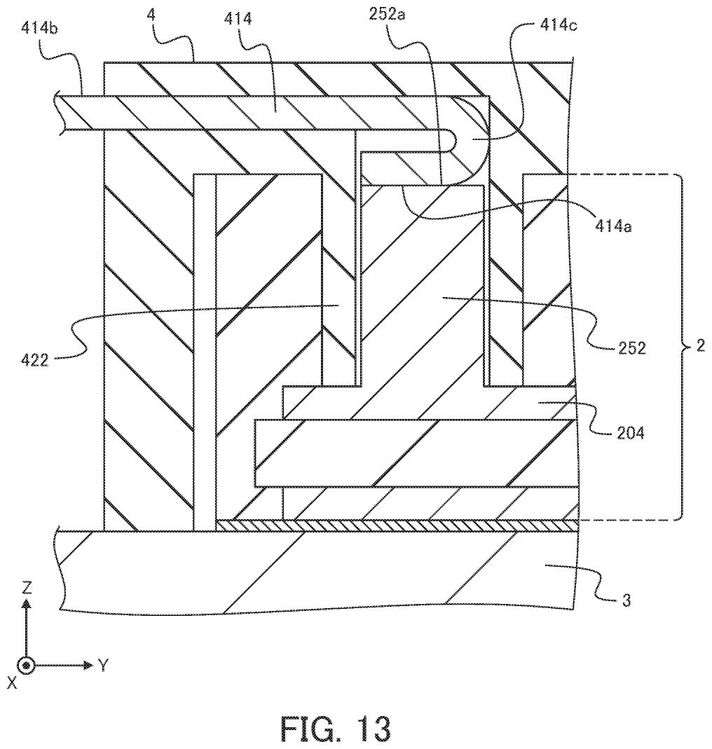

FIG. 12 is a cross-sectional side view for explaining a modification of the conductive member provided in the case. FIG. 13 is a cross-sectional side view illustrating a state of a connection portion between the terminal portion of the conductor pattern of the semiconductor package and the conductive member of the case in the semiconductor device using the case in FIG. 12.

In a conductive member 414 provided in the case 4 illustrated in FIG. 12, a deformation allowing portion 414c is provided between a contact portion 414a facing the housing portion 401 and an external terminal portion 414b exposed from the outer surface of the case 4. The deformation allowing portion 414c is a portion that allows deformation of the conductive member 414 due to a pressing load, when the terminal portion (for example, terminal portion 252 of third conductor pattern 204) provided in the conductor pattern of the semiconductor package 2 has contact with the contact portion 414a and the pressing load is applied when the cooler 3 in which the semiconductor package 2 is arranged is attached to the case 4. For example, as illustrated in FIGS. 12 and 13, the deformation allowing portion 414c is provided to be able to change an angle of an extending direction of the contact portion 414a with respect to an extending direction of the external terminal portion 414b starting from the deformation allowing portion 414c. The change of the angle by the deformation allowing portion 414c may be caused by elastic deformation or plastic deformation. By providing the deformation allowing portion 414c in the conductive member 414 provided in the case 4, it is possible to avoid a loose connection between the terminal portion of the conductor pattern of the semiconductor package 2 and the conductive member of the case 4, that may occur within a range of a tolerance.

Note that a shape of the deformation allowing portion 414c, a type of the deformation caused by the pressing load, or the like are not limited to specific ones. Furthermore, instead of providing the portion deformed by the pressing load such as the deformation allowing portion 414c, in the conductive member provided in the case 4, for example, a member having cushioning properties may be arranged between the upper surface of the conductive member and a portion above the conductive member in the case 4.

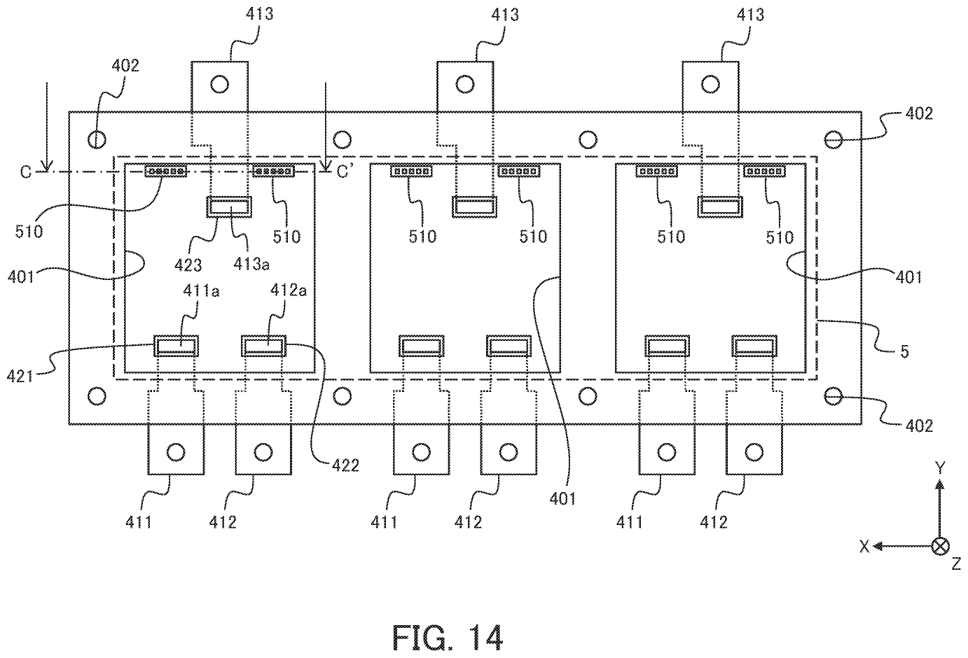

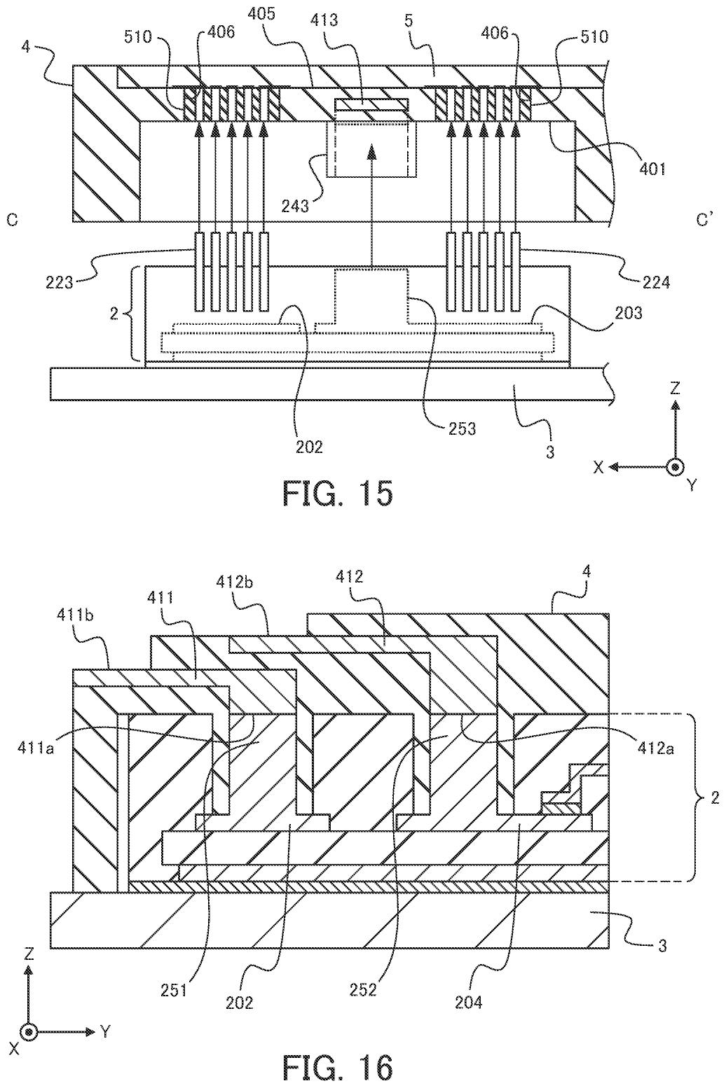

FIG. 14 is a bottom view illustrating a configuration example of the case incorporating a control circuit. FIG. 15 is a cross-sectional side view illustrating a configuration example of the case taken along a C-C′ line in FIG. 14. Note that, in FIG. 15, the cross-sectional side view of the case 4 when a portion lower than the C-C′ line in FIG. 14 of the case 4 is viewed from a front side in the X direction and the cooler 3 in which the semiconductor package 2 is arranged are illustrated.

In the semiconductor device 1 illustrated in FIGS. 1 and 4, the second attaching unit 403 is provided on the upper surface of the case 4, and a gap corresponding to the height (dimension in Z direction) of the second attaching unit 403 is generated between the case 4 and the control circuit 5. In such a semiconductor device 1, for example, an influence of a part of heat generated in the semiconductor package 2 on the control circuit 5 can be reduced.

On the other hand, in the semiconductor device 1 illustrated in FIGS. 14 and 15, the control circuit 5 is fitted into a recessed third attaching portion (circuit component attaching portion) 405 provided on the upper surface of the case 4. In a bottom surface of the third attaching portion 405, through-holes 406 are provided in which a connector 510 in which the leads (control terminal) 223 and 224 of the semiconductor package 2 are inserted is fitted. When a depth of the third attaching portion 405 is set to be substantially the same as a thickness of the control circuit 5, a protrusion amount of the control circuit 5 from the upper surface of the case 4 becomes substantially zero, and this is advantageous for reducing the height of the semiconductor device 1. Furthermore, by incorporating the control circuit 5 in the case 4, it is possible to prevent deterioration or the like caused by exposing the third lead 223 and the fourth lead 224 protruding from the semiconductor package 2 to outside air. Moreover, by incorporating the control circuit 5 in the case 4, an assembly work of the semiconductor device 1 can be simplified.

Furthermore, in the semiconductor device 1 illustrated in FIGS. 1, 14, or the like, layouts of the conductive members 411 to 413 provided in the case 4 do not overlap each other in plan view. However, the layout of the conductive member provided in the case 4 is not limited to such a layout.

FIG. 16 is a cross-sectional diagram for explaining another example of a layout of the conductive member provided in the case.

In the case 4 of the semiconductor device 1 illustrated in FIG. 16, the external terminal portion 412b of the conductive member 412 that functions as the second input terminal (N terminal) in the inverter device 11 described above with reference to FIG. 5 is arranged to overlap on the conductive member 411 that functions as the first input terminal (P terminal). With such an arrangement, areas of an external terminal portion 411b of the conductive member 411 and the external terminal portion 412b of the conductive member 412 can be increased, and for example, this is advantageous in a case where a larger current flows.

Furthermore, circuit components used for the circuit formed on the wiring board 200 of the semiconductor package 2 are not limited to those having the above configurations. For example, the semiconductor elements 211 and 212 may include a Reverse Conducting (RC)-SiC-MOS element in which functions of a Silicon Carbide-MOS (SiC-MOS) element and a SiC-Free Wheeling Diode (SiC-FWD) element are integrated. Moreover, a Reverse Blocking (RB)-IGBT or the like having a sufficient withstand voltage against a reverse bias may be used as a semiconductor element. The shape, number, placement, and the like of the semiconductor element can be changed as appropriate. The layout of the conductor pattern as the wiring member provided on the upper surface side of the wiring board 200 is changed according to the type and shape of the semiconductor element to be mounted, the number of the semiconductor elements to be arranged, the placement of the semiconductor elements, and the like. Furthermore, in the conductor pattern as the wiring member provided on the upper surface side of the wiring board 200, all the conductor patterns in which the terminal portions are provided may be arranged on the insulating substrate 201, separately from the conductor pattern bonded to the electrode on the lower surface of the semiconductor element. For example, the terminal portion 251 provided on the first conductor pattern 202 in the semiconductor package 2 illustrated in FIG. 3 may be provided on a conductor pattern different from the first conductor pattern 202, electrically connected to the first conductor pattern 202 with the lead. By separating the conductor pattern in which the semiconductor element is arranged from the conductor pattern in which the terminal portion is provided, for example, it is possible to reduce an influence of stress generated around the terminal portion when the cooler 3 in which the semiconductor package 2 is arranged is attached to the case 4 or after the attachment, on the conductor pattern in which the semiconductor element is arranged. Furthermore, the terminal portions 251 to 253 provided in the semiconductor package 2 are not limited to be formed integrally with the conductor pattern formed on the upper surface of the insulating substrate 201, and may be a block-shaped conductive component bonded to the upper surface of the conductor pattern.

Moreover, instead of using the single semiconductor element 211 in which the switching element and the diode element used for the inverter circuit are integrated, the switching element and the diode element may be combined with a semiconductor element that functions as a switching element and a semiconductor element that functions as a diode element. The semiconductor element that functions as the switching element may include, for example, Silicon Carbide (SiC), an IGBT, a power MOSFET, a Bipolar Junction Transistor (BJT), or the like. The semiconductor element that functions as the diode element may include, for example, a Free Wheeling Diode (FWD), a Schottky Barrier Diode (SBD), a Junction Barrier Schottky (JBS) diode, a Merged PN Schottky (MPS) diode, a PN diode, or the like, and a formation substrate thereof may be silicon (Si) or SiC.

Furthermore, an example of the semiconductor device 1 has been described in which the cooler 3 or a holding member such as a base plate in which the semiconductor package 2 is arranged is attached to the case 4. However, a method for providing circuit components included in the semiconductor device 1 is not limited to a specific method. For example, the case 4 in which the semiconductor package 2 is housed in the housing portion 401 may be provided as a “semiconductor module”, separately from the cooler 3 or the holding member such as the base plate and the control circuit 5.

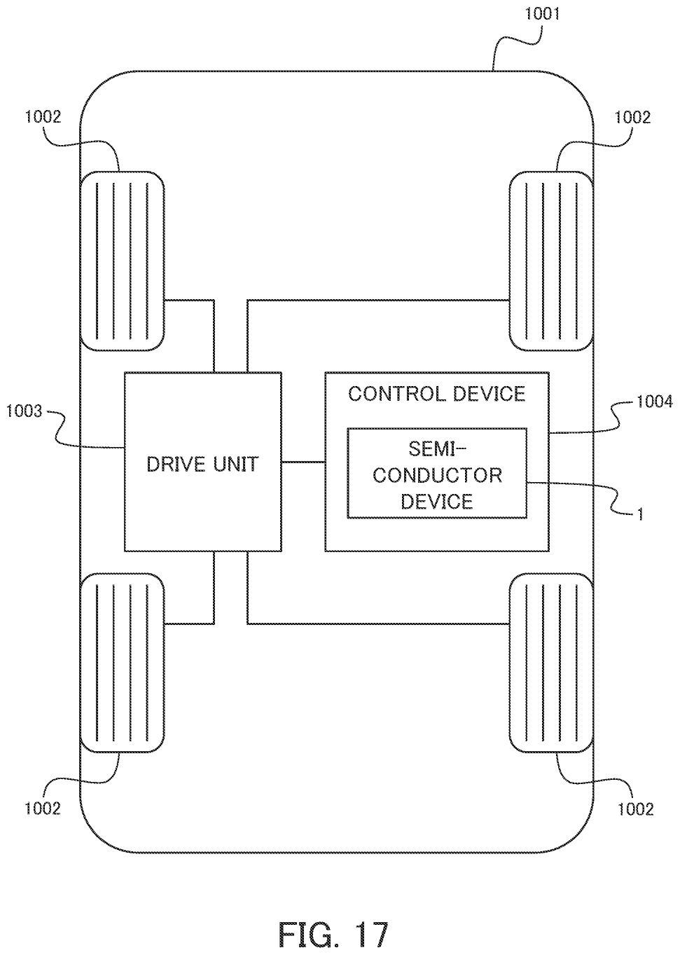

The semiconductor device 1 according to the above embodiment is not limited to a specific application. However, in particular, the semiconductor device 1 is suitable for use in a high-temperature and high-humidity environment. For example, the semiconductor device 1 according to the above embodiment may be applied to a power conversion device such as an inverter device of an in-vehicle motor or the like. A vehicle to which the semiconductor device 1 according to the present invention is applied is described with reference to FIG. 17.

FIG. 17 is a schematic plan view illustrating an example of a vehicle to which the semiconductor device according to the present invention is applied. A vehicle 1001 illustrated in FIG. 17 includes, for example, a four-wheeled vehicle including four wheels 1002. The vehicle 1001 may be, for example, an electric vehicle that drives wheels by a motor or the like, or a hybrid vehicle using power of an internal combustion engine in addition to the motor.

The vehicle 1001 includes a drive unit 1003 that applies power to the wheels 1002, and a control device 1004 that controls the drive unit 1003. The drive unit 1003 may include, for example, at least one of an engine, a motor, and a hybrid of an engine and a motor.

The control device 1004 controls (for example, power control) the drive unit 1003. The control device 1004 includes the semiconductor device 1 including the semiconductor package 2 according to the above embodiment. The semiconductor device 1 may be configured to perform power control on the drive unit 1003. The semiconductor device 1 may have a configuration in which a heat dissipation member such as a heat sink that dissipates heat generated in the semiconductor package 2, the cooler 3 that cools the semiconductor package 2 or the heat dissipation member, and the like are attached to the semiconductor package 2. The semiconductor device 1 may include the plurality of semiconductor packages 2.

Furthermore, the embodiments of the semiconductor package 2 and the semiconductor device 1 according to the present invention are not limited to the above embodiments, and various changes, substitutions, and modifications may be made without departing from the spirit of the technical idea. When the technical idea can be realized in another manner by the progress of the technology or another derived technology, the technology may be implemented by using the manner. Thus, the claims cover all implementations that may be included within the scope of the technical idea.

In the following, feature points in the above embodiment are summarized.

A semiconductor module according to the above embodiment includes a sealing body in which a terminal portion electrically connected to an electrode of a semiconductor element is exposed from an insulating resin that seals the semiconductor element, a case including a housing portion that houses the sealing body, and a conductive member provided in the case and including a contact portion that has contact with the terminal portion of the sealing body in a case where the sealing body is housed in the housing portion of the case and an external terminal portion exposed from an outer surface of the case, in which the case includes a holding member attaching portion that is used in combination with the case and is capable of attaching a holding member that holds the sealing body housed in the housing portion in a state where the terminal portion of the sealing body has contact with the contact portion of the conductive member, and the holding member attaching portion of the case is configured so that a pressing load is applied to a contact surface between the terminal portion of the sealing body and the contact portion of the conductive member when the holding member is attached.

In the semiconductor module, the terminal portion of the sealing body is exposed to a first surface of the sealing body, and the housing portion of the case has a recessed shape that has a bottom surface facing the first surface of the insulating resin of the sealing body when the sealing body is housed and of which a second surface side opposite to the first surface of the sealing body opens.

In the semiconductor module, the sealing body has a groove portion formed along an outer periphery of the terminal portion in the first surface, and the housing portion of the case has a convex portion on the bottom surface that enters the groove portion of the sealing body when the sealing body is housed.

In the semiconductor module, the terminal portion of the sealing body is exposed outside a region where the semiconductor element is sealed, in plan view of the first surface of the sealing body.

In the semiconductor module, the terminal portion of the sealing body and the electrode of the semiconductor element are electrically connected via one or more wiring members.

In the semiconductor module, the case is capable of housing a plurality of the sealing bodies.

In the semiconductor module, the sealing body includes a second terminal portion that is electrically connected to a second electrode different from the electrode that is electrically connected to the terminal portion of the semiconductor element and exposed from the insulating resin, and the case has a circuit component attaching portion to which a circuit component that inputs an electrical signal in the semiconductor element via the second terminal portion of the sealing body is attached.

In the semiconductor module, the sealing body includes a second terminal portion that is electrically connected to a second electrode different from the electrode that is electrically connected to the terminal portion of the semiconductor element and exposed from the insulating resin, and the case incorporates a circuit component that inputs an electrical signal to the semiconductor element via the second terminal portion of the sealing body.

In the semiconductor module, the sealing body includes a conductor layer exposed to the second surface.

In the semiconductor module, in the conductive member of the case, a portion is provided that is deformed by a pressing load when the contact surface of the contact portion having contact with the terminal portion of the sealing body receives the pressing load.

In the semiconductor module, the holding member attaching portion of the case is formed at a position to be an outer peripheral portion of a surface to which the holding member is attached, in plan view.

In the semiconductor module, the holding member attaching portion of the case is formed at a position corresponding to a corner of the sealing body housed in the housing portion in plan view.

The semiconductor device according to the above embodiment includes the semiconductor module and the holding member attached to the holding member attaching portion of the case.

In the semiconductor device, the terminal portion of the sealing body and the contact portion of the case are connected via an adhesive conductor layer.

In the semiconductor device, the terminal portion of the sealing body and the contact portion of the case are partially welded within a contact surface.

In the semiconductor device, the holding member is a cooler bonded to the conductor layer of the sealing body in the semiconductor module with a bonding material.

The vehicle according to the above embodiment includes the semiconductor device.

As described above, the present invention achieves an effect that it is possible to increase a current flowing in a semiconductor device while suppressing an increase in manufacturing cost, and in particular, the present invention is useful for a semiconductor module for industrial or electrical equipment, a semiconductor device, and a vehicle.

What is claimed is:

1. A semiconductor module, comprising:
a sealing body including a semiconductor element, a terminal portion electrically connected to a first electrode of the semiconductor element, and an insulating resin that seals the semiconductor element, the terminal portion being exposed from the insulating resin;
a case including a housing portion that houses the sealing body; and
a conductive member provided in the case and including a contact portion that has contact with the terminal portion of the sealing body when the sealing body is housed in the housing portion of the case and an external terminal portion is exposed from an outer surface of the case, wherein
the case includes a holding member attaching portion capable of attaching a holding member that is used in combination with the case and holds the sealing body in a state where the terminal portion of the sealing body has contact with the contact portion of the conductive member, and
the holding member attaching portion of the case is configured so that a pressing load is applied to a contact surface of the contact portion of the conductive member contacting the terminal portion of the sealing body when the holding member is attached.

2. The semiconductor module according to claim 1, wherein
the terminal portion of the sealing body is exposed to a first surface of the sealing body, and
the case has a first surface and a second surface opposite to each other, the housing portion of the case being recessed from the second surface of the case toward the first surface of the case, the housing portion having a bottom surface facing the first surface of the sealing body housed in the housing portion.

3. The semiconductor module according to claim 2, wherein
the sealing body has in the first surface thereof, a groove formed along an outer periphery of the terminal portion, and
the housing portion of the case has a convex portion on the bottom surface that enters the groove of the sealing body when the sealing body is housed.

4. The semiconductor module according to claim 2, wherein
in a plan view of the semiconductor module, the terminal portion of the sealing body is exposed outside a region where the semiconductor element is sealed.

5. The semiconductor module according to claim 4, further comprising one or more wiring members that electrically connects the terminal portion of the sealing body to the first electrode of the semiconductor element.

6. The semiconductor module according to claim 1, wherein
the sealing body is provided in plurality and the case houses the plurality of sealing bodies.

7. The semiconductor module according to claim 1, wherein
the sealing body includes a second terminal portion that is electrically connected to a second electrode of the semiconductor element that is different from the first electrode of the semiconductor element and is exposed from the insulating resin, and
the case has a circuit component attaching portion to which a circuit component that inputs an electrical signal in the semiconductor element via the second terminal portion of the sealing body is attached.

8. The semiconductor module according to claim 1, wherein
the sealing body includes a second terminal portion that is electrically connected to a second electrode of the semiconductor element that is different from the first electrode of the semiconductor element and is exposed from the insulating resin, and
the case incorporates a circuit component that inputs an electrical signal to the semiconductor element via the second terminal portion of the sealing body.

9. The semiconductor module according to claim 2, wherein
the sealing body includes a conductor layer exposed to a second surface of the sealing body that is opposite to the first surface of the sealing body.

10. The semiconductor module according to claim 1, wherein
the conductive member of the case has a portion that is deformed by the pressing load when the pressing load is applied to the contact surface of the contact portion when the terminal portion of the sealing body contacts the contact portion.

11. The semiconductor module according to claim 1, wherein
the holding member attaching portion of the case is provided at an outer periphery of a surface to which the holding member is attached.

12. The semiconductor module according to claim 11, wherein
the holding member attaching portion of the case is provided at a position corresponding to a position of a corner of the sealing body housed in the housing portion in a plan view of the semiconductor module.

13. A semiconductor device, comprising:
the semiconductor module according to claim 1; and
the holding member attached to the holding member attaching portion of the case.

14. The semiconductor device according to claim 13, wherein the terminal portion of the sealing body and the contact portion of the conductive member are connected via an adhesive conductor layer.

15. The semiconductor device according to claim 13, wherein the terminal portion of the sealing body and the contact portion of the conductive member are partially welded within an area of the contact surface.

16. The semiconductor device according to claim 13, wherein
the sealing body includes a conductor layer exposed from the sealing body, and
the holding member is a cooler bonded to the conductor layer of the sealing body with a bonding material.

17. A vehicle comprising: the semiconductor device according to claim 13.
